(19) United States
(12) Patent Application Publication
(10) Pub. No.: US 2012/0313504 A1
(43) Pub. Date: Dec. 13, 2012

(54) FILM-FORMING DEVICE AND LIGHT-EMITTING DEVICE

(75) Inventors: Hiroshi SASAKI, Osaka-shi (JP); Takanori Sonoda, Osaka-shi (JP)

(73) Assignee: Sharp Kabushiki Kaisha, Osaka-shi (JP)

(21) Appl. No.: 13/419,616

(22) Filed: Mar. 14, 2012

(30) Foreign Application Priority Data
Jun. 7, 2011 (JP) 2011-127133

(51) Int. Cl. H01J 1/02; C23C 14/35

(52) U.S. Cl. 313/311; 204/298.19; 204/298.08

(57) ABSTRACT

A film-forming device includes: a shield part placed so as to surround the sides of the target; a rod-shaped magnetic field generation unit for generating a magnetic field, the magnetic field generation unit being placed toward the back surface of the target; and a drive unit for reciprocatingly driving the magnetic field generation unit in a linear manner along a drive direction, which is a direction perpendicular to the length direction of the magnetic field generation unit, in a horizontal plane, which is a plane perpendicular to the front/back direction of the target. When the magnetic field generation unit is located at the end of the range within which it is driven by the drive unit, the distance in the drive direction between the magnetic field generation unit and the projection when the shield part is projected perpendicularly to the horizontal plane is 10 mm or more.

### CROSS REFERENCE TO RELATED APPLICATION

This Nonprovisional application claims priority under 35 U.S.C. §119(a) on Patent Application No. 2011-127133 filed in Japan on Jun. 7, 2011 the entire contents of which are hereby incorporated by reference.

### BACKGROUND OF THE INVENTION

1. Field of the Invention

The present invention relates to a film-forming device for forming a film, and to a light-emitting device provided with an electrode formed by the film-forming device.

2. Description of the Related Art

In recent years, transparent electrodes made of indium tin oxide (ITO) and the like have been used in light-emitting diodes (LEDs), organic ELs, liquid crystal displays, touch panels, and various other optical devices. One film-forming device for such transparent electrodes is a magnetron sputtering device (see “Transparent conductive film technology”, edited by The 166th Committee of Transparent Oxide and Photoelectron Materials, Japan Society for the Promotion of Science, Ohmsha, Ltd. May 2008, pp. 218-221 (hereinafter, “Publicly Known Document 1”).

A magnetron sputtering device is capable of quickly sputtering a target by generating plasma in the vicinity of the front surface of the target by a magnet or the like placed toward the back surface of the target. However, a magnetron sputtering device is problematic in that the target is locally consumed (eroded) when the space where plasma is generated is limited.

To counter this problem, for example, Japanese Laid-open Patent Publication No. H8-199354 proposes a magnetron sputtering device which causes the target to be consumed uniformly and achieves homogenization of the generated film by rendering the distance between the magnet and the target variable, thus causing the state of the generated plasma to change.

In the aforesaid magnetron sputtering device, the sheath voltage (discharge voltage) varies in accordance with the strength of the magnetic field generated by the magnet. A more detailed description shall now be provided, with reference to FIG. 6. FIG. 6 is a graph illustrating the relationship between magnetic flux density and the sheath voltage. The horizontal axis of the graph is the magnetic flux density (T), and the vertical axis is the absolute value of the sheath voltage (V). The graph illustrated in FIG. 6 is based on the summary recited in the aforesaid Publicly Known Document 1.

As illustrated in FIG. 6, an increase in the magnetic flux density corresponds to a decrease in the absolute value of the sheath voltage. This is because an increase in the magnetic flux density corresponds to an increase in the plasma density over the target. When the absolute value of the sheath voltage is decreased, it is possible to decrease the energy of target particles (hereinafter refers to the particles generated by the sputtering of the target) colliding with the substrate or a film on the substrate. That is, it becomes possible to form a less damaged film.

However, in the case where the magnetic flux density is increased to decrease the absolute value of the sheath voltage, the magnet becomes either larger or more complex, which is accompanied by the device becoming larger or more complex or by it becoming necessary to extensively modify the design of the device, which is problematic. An additional problem is that even though the absolute value of the sheath voltage can be decreased, when the temporal fluctuations thereof are large, the film formed will not be homogeneous.

### SUMMARY OF THE INVENTION

The present invention has been contrived in view of the aforesaid problems, and an object thereof is to provide a film-forming device capable of forming a film that has less damage and is homogeneous, and a light-emitting device using a film formed by the film-formed device as an electrode.

To achieve the aforesaid objective, the present invention provides a film-forming device for forming, on a substrate placed toward the front surface of a target, a film containing the material constituting the target, by sputtering the target with plasma, the film-forming device comprising:

a chamber in the interior of which the film is formed;

a shield part placed within the chamber so as to surround the sides of the target;

a rod-shaped magnetic field generation unit for generating a magnetic field, the magnetic field generation unit being placed inside the shield part and toward the back surface of the target; and

a drive unit for reciprocatingly driving the magnetic field generation unit in a linear manner along a drive direction, which is a direction perpendicular to the length direction of the magnetic field generation unit, in a horizontal plane, which is a plane perpendicular to the front/back direction of the target; wherein

when the magnetic field generation unit is located at the end of the range within which the magnetic field generation unit is driven by the drive unit, the distance in the drive direction between the magnetic field generation unit and the projection when the shield part is projected perpendicularly to the horizontal plane is 10 mm or more.

Preferably, in the film-forming device having the aforesaid feature, when the magnetic field generation unit is located at the end of the range within which the magnetic field generation unit is driven by the drive unit, the distance in the drive direction between the magnetic field generation unit and the projection when the shield part is projected perpendicularly to the horizontal plane is 20 mm or more.

Preferably, in the film-forming device having the aforesaid feature, the polarity of the magnetic field generation unit on the target side and on the outer peripheral side in the horizontal plane is different from the polarity of the magnetic field generation unit on the target side and on the center side in the horizontal plane.

Preferably, in the film-forming device having the aforesaid feature, when the magnetic field generation unit is located at the end of the range within which the magnetic field generation unit is driven by the drive unit, the distance in the drive direction between the magnetic field generation unit and the projection when the shield part is projected perpendicularly to the horizontal plane is 30 mm or less.

Preferably, in the film-forming device having the aforesaid feature, the drive unit drives the magnetic field generation unit at a speed of 10 mm/s or more and 20 mm/s or less.

Preferably, in the film-forming device having the aforesaid feature, the distance between the substrate and the target is 50 mm or more and 150 mm or less, and

the distance between the target and the magnetic field generation unit is 15 mm or more and 30 mm or less.

Preferably, in the film-forming device having the aforesaid feature, the magnetic flux density of the region facing the magnetic field generation unit in the front surface of the target is 0.03 T or more and 0.12 T or less.

Preferably, in the film-forming device having the aforesaid feature, the interior of the chamber when the film is being formed is an argon atmosphere of 0.4 Pa or more and 1 Pa or less.

Preferably, in the film-forming device having the aforesaid feature, the temperature of the substrate when the film is being formed is 50° C. or less.

Preferably, in the film-forming device having the aforesaid feature, the direct current power supplied to the target when the film is being formed is 200 W or more and 1,200 W or less.

The present invention also provides a film-forming device for forming, on a substrate placed toward the front surface of a target, a film containing the material constituting the target, by sputtering the target with plasma, the film-forming device comprising:

a chamber in the interior of which the film is formed;

a shield part placed within the camber so as to surround the sides of the target;

a magnetic field generation unit for generating a magnetic field, the magnetic field generation unit being placed inside the shield part and toward the back surface of the target; and

a drive unit for driving the magnetic field generation unit in a horizontal plane, which is a plane perpendicular to the front/back direction of the target; wherein

when the magnetic field generation unit is located at the end of the range within which the magnetic field generation unit is driven by the drive unit, the distance between the magnetic field generation unit and the projection when the shield part is projected perpendicularly to the horizontal plane is 10 mm or more.

The present invention further provides a light-emitting device, comprising an electrode made of indium tin oxide formed using the film-forming device having the aforesaid features.

According to the film-forming device having the aforesaid features, it is possible to decrease the absolute value and fluctuations of the sheath voltage merely by limiting the drive range of the magnetic field generation unit. It therefore becomes possible to form a film that has less damage and is homogeneous.

### BRIEF DESCRIPTION OF THE DRAWINGS

FIG. 1 is a cross-sectional view illustrating an example of the structure of a film-forming device according to an embodiment of the present invention;

FIG. 2 is a plan view illustrating a method for driving the magnetic field generation unit of the film-forming device illustrated in FIG. 1;

FIG. 3 is a graph illustrating the relationship between the sheath voltage and the central position of the magnetic field generation unit in a comparative example and in a working example;

FIG. 4 is a graph illustrating the relationship between the sheath voltage and the film formation time in a comparative example and in a working example;

FIG. 5 is a graph illustrating the characteristics of elements provided with films formed by respective film-forming devices in which the comparative example and the working example have been adopted; and

FIG. 6 is a graph illustrating the relationship between magnetic flux density and the sheath voltage.

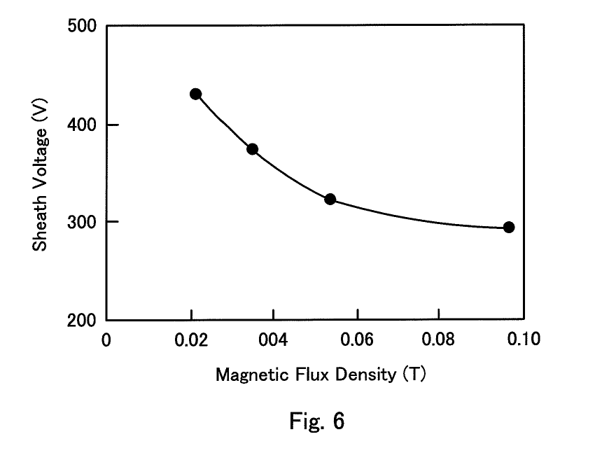

### DESCRIPTION OF THE PREFERRED EMBODIMENTS

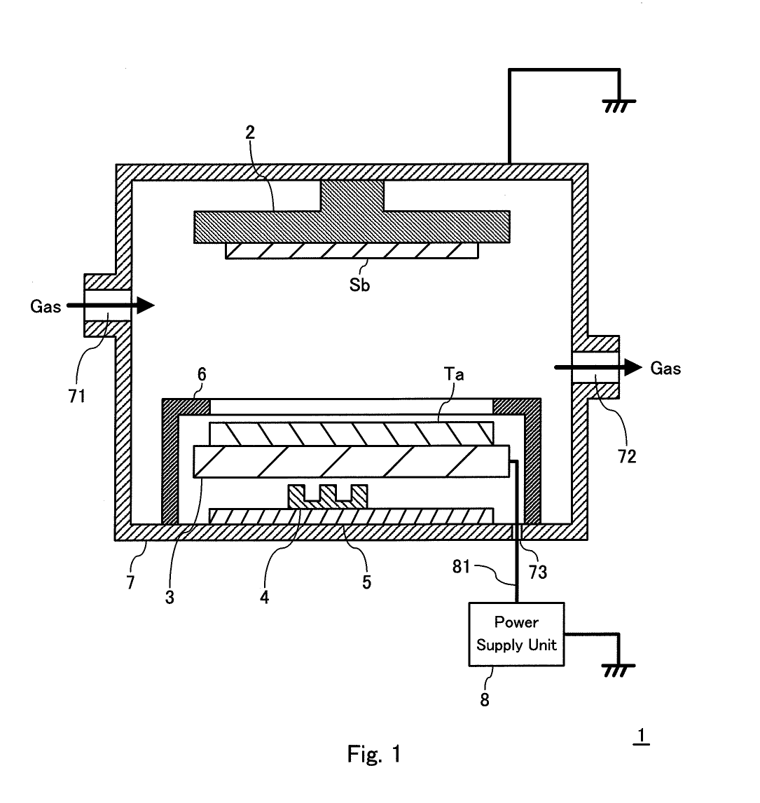

The following is a description of a film-forming device (a magnetron sputtering device) according to an embodiment of the present invention, with reference to the accompanying drawings. Firstly, a description of an example of the structure of the film-forming device according to the embodiment of the present invention shall now be provided, with reference to FIG. 1. FIG. 1 is a cross-sectional view illustrating an example of the structure of a film-forming device according to the embodiment of the present invention.

As illustrated in FIG. 1, a film-forming device 1 is provided with: a stage 2 on which a substrate Sb is installed; a backing plate 3 on which a target Ta is installed; a magnetic field generation unit 4 for generating a magnetic field; a drive unit 5 for driving the magnetic field generation unit 4; a shield part 6 provided to the periphery of the target Ta and the backing plate 3; a chamber 7 in the interior of which a film is formed, the chamber 7 being grounded; and a power supply unit 8 for supplying power to the backing plate 3, the power supply unit 8 being placed outside of the chamber 7. Below, to provide a more specific description, an example is presented for a case where the power supply unit 8 supplies direct current power having a negative voltage to the backing plate 3.

The stage 2 is grounded by being electrically connected to the chamber 7, and serves as a positive electrode. The backing plate 3 is supplied with direct current power having a negative voltage from the power supply unit 8, and serves as a negative electrode. In the film-forming device 1 illustrated in FIG. 1, the surface of the stage 2 on which the substrate Sb is installed faces the surface of the backing plate 3 on which the target Ta is installed. That is, the substrate Sb and the target Ta are facing. Hereinafter, the surface of the target Ta closer to the substrate Sb (the upper direction in FIG. 1) is a front surface, and the surface closer to the opposite side (closer to the backing plate 3; the lower direction in FIG. 1) is a back surface. The direction in which the substrate Sb is present when viewed from the target Ta is expressed as a front surface direction or an upper direction, while the direction in which the backing plate 3 is present when viewed from the target Ta is expressed as a back surface direction or a lower direction.

The magnetic field generation unit 4 is made of, for example, a permanent magnet, an electromagnet, or another element capable of generating a magnetic field. The drive unit 5 drives the magnetic field generation unit 4 within a plane perpendicular to the front/back direction (up-down direction) of the target Ta (the plane includes the left-right direction of FIG. 1 and the front-rear direction of the paper, and is hereinafter the “horizontal plane”). A more detailed description of the method by which the drive unit 5 drives the magnetic field generation unit 4 shall be provided below. The magnetic field generation unit 4 and the drive unit 5 are placed toward the back surface of the target Ta (in particular, the space between the wall surface of the chamber 7 and the backing plate 3, and inside the shield part 6).

The shield part 6 is grounded by being electrically connected to the chamber 7. The shield part 6 is placed so as to surround the sides of the backing plate 3 and the target Ta. The upper side end part of the shield part 6 is bent inward (toward the upper side of the target Ta). The plasma generated inside the chamber 7 is thereby inhibited from sputtering the backing plate 3.

FIG. 1 depicts a structure in which the tip of the bent portion of the shield part 6 is pushed out over the edge of the target Ta, but the tip of the bent portion of the shield part 6 may also be further inward than the state illustrated in FIG. 1, or may be further outward. In such cases as where, for example, the backing plate 3 is of a substantially equivalent size to that of the target Ta, the aforesaid bent portion need not be provided to the shield part 6.

Each of the aforesaid parts (the stage 2, the backing plate 3, the magnetic field generation unit 4, the drive unit 5, and the shield part 6) are provided to the interior of the chamber 7. The chamber 7 is further provided with an inlet 71 for introducing gas for generating plasma (for example, argon gas) to the interior, and an outlet 72 for discharging the gas inside the chamber 7. The gas is introduced into the inlet 71 at a flow rate controlled by, for example, a mass flow controller. The outlet 72 is connected to a vacuum pump or the like, by which gas inside the chamber 7 is discharged. The gas inside the chamber 7 is thereby maintained in a desired state.

The chamber 7 is further provided with a connection port 73. A power supply cable 81 passes through the connection port 73 to electrically connect the backing plate 3 with the power supply unit 8, placed outside the chamber 7. The power supply unit 8 supplies direct current power having a negative voltage to the backing plate 3 via the power source cable 81.

When the power supply unit 8 supplies direct current power having a negative voltage to the backing plate 3, a dielectric breakdown occurs between the backing plate 3, which is a negative electrode, and the stage 2, which is a positive electrode; the gas within the chamber 7 becomes ionized and plasma is generated. At such a time, the magnetic field generated by the magnetic field generation unit 4 causes plasma to generate in the vicinity of the target Ta. Therefore, the ions in the plasma are efficiently collided with the target Ta, and the target Ta is efficiently sputtered. Also, when the target particles created by the sputtering reach the substrate Sb, a film containing the material constituting the target Ta is formed on the substrate Sb.

In the film-forming device 1 according to the embodiment of the present invention, the drive unit 5 drives the magnetic field generation unit 4 to change the spot where the plasma is generated. The consumption of the target Ta is thereby rendered uniform.

The film-forming device 1 according to the embodiment of the present invention can employ the following film-forming conditions, by way of an example. The film-forming conditions are: a distance of 90 mm between the substrate Sb and the target Ta; a distance of 25 mm between the target Ta and the magnetic field generation unit 4; a speed of 16.2 mm/s by which the drive unit 5 drives the magnetic field generation unit 4; a magnetic flux density of 0.03 T or more and 0.12 T or less in the region facing the magnetic field generation unit 4; a pressure of 0.67 Pa inside the chamber 7 when a film is being formed (where the flow rate of argon gas being introduced from the inlet 71 is 100 sccm); a substrate Sb temperature of 50° C. or less (the substrate is not heated); and a direct current power of 300 W being supplied to the target Ta (the backing plate 3) when a film is being formed. In the following description, unless there is particular mention, the film-forming device 1 is understood to employ such film-forming conditions.

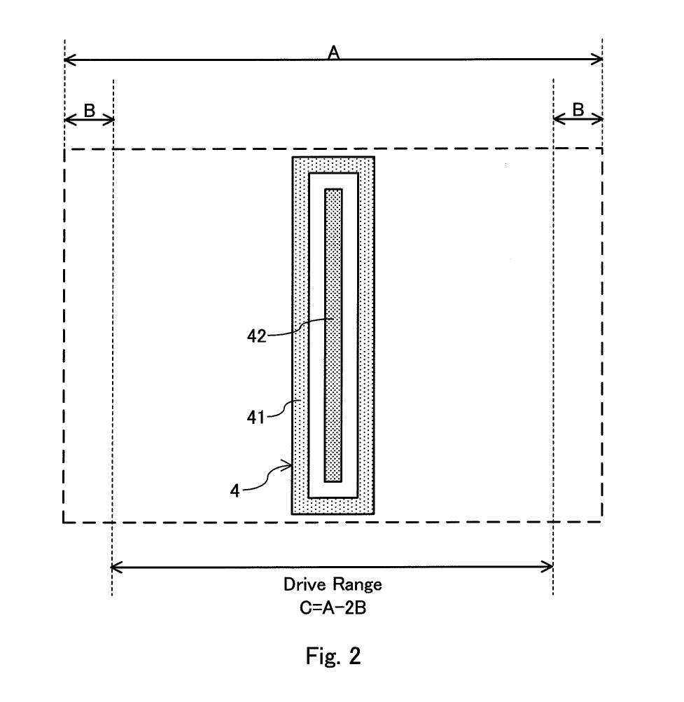

A description of the method for driving the magnetic field generation unit 4 in the film-forming device 1 according to the embodiment of the present invention shall now be provided, with reference to FIG. 2. FIG. 2 is a plan view illustrating a method for driving the magnetic field generation unit of the film-forming device illustrated in FIG. 1. FIG. 2 is a plan view illustrating the state where the horizontal plane on which the magnetic field generation unit 4 is driven is viewed from the stage 2 side (the upper side). In FIG. 2, a dashed line is used to display the projection where the outer peripheral end of the target Ta and the inner peripheral end of the shield part 6 are projected perpendicularly to the horizontal plane.

The magnetic field generation unit 4 depicted in FIG. 2 is overall in the shape of a rod. The magnetic field generation unit 4 is further provided with an outer peripheral part 41 placed at the outer periphery in the horizontal plane, and a center part 42 placed to the inside (toward the center) of the outer peripheral part 41 in the horizontal plane. The outer peripheral part 41 and the center part 42 have different polarities on the target Ta side (the upper side). Specifically, for example, the polarity of the outer peripheral part 41 on the target Ta side is N, and the polarity of the center part 42 on the target Ta side is S.

In this manner, when the outer peripheral part 41 and the center part 42 of the magnetic field generation unit 4 are given different polarities, the magnetic field can be inhibited from expanding uselessly (i.e., the spot where the plasma is generated can be inhibited from expanding uselessly), which is preferable. Each of the outer peripheral part 41 and the center part 42 may be made of different magnets or electromagnets, or may be made of different portions of a single magnet or electromagnet.

The drive unit 5 reciprocatingly drives the magnetic field generation unit 4 in a linear manner along a direction perpendicular to the length direction of the magnetic field generation unit 4 (the left-right direction in FIG. 2; hereinafter, the “drive direction”).

As described above, in the case based on the standpoint of rendering the consumption of the target Ta uniform (causing plasma to be generated evenly throughout the vicinity of the front surface of the target Ta), the drive unit 5 is set such that the magnetic field generation unit 4 is maximally driven. In such a case, as a specific example, the entirety of the region directly below the target Ta (within the projection where the target Ta is projected perpendicularly to the horizontal plane; the region inside the dashed line illustrated in FIG. 2) serves as the range within which the magnetic field generation unit 4 is driven (hereinafter, the “drive range”). That is, the drive range of the magnetic field generation unit 4 in such a case is the range of A in FIG. 2. In the description below, the case where the drive range of the magnetic field generation unit 4 as described above is A serves as a “comparative example”.

By contrast, in the film-forming device 1 according to the embodiment of the present invention, the drive range of the magnetic field generation unit 4 is rendered narrower than the aforesaid comparative example. Specifically, the positions where the distance in the drive direction between the magnetic field generation unit 4 and the projection when the shield part 6 is projected perpendicularly to the horizontal plane (the region outside the dashed line illustrated in FIG. 2) reaches B serve as the ends of the drive range of the magnetic field generation unit 4 (the two ends in the drive direction). That is, the drive range of the magnetic drive generation unit 4 in the film-forming device 1 according to the embodiment of the present invention is C in FIG. 2 (where C=A−2B). In the description below, the case where the drive range of the magnetic field generation unit 4 as described above is C serves as a “working example”.

A specific description of the comparative example and the working example shall now be provided, with reference to the following drawings. In the working example in the following description, the value of the aforesaid B is 20 mm.

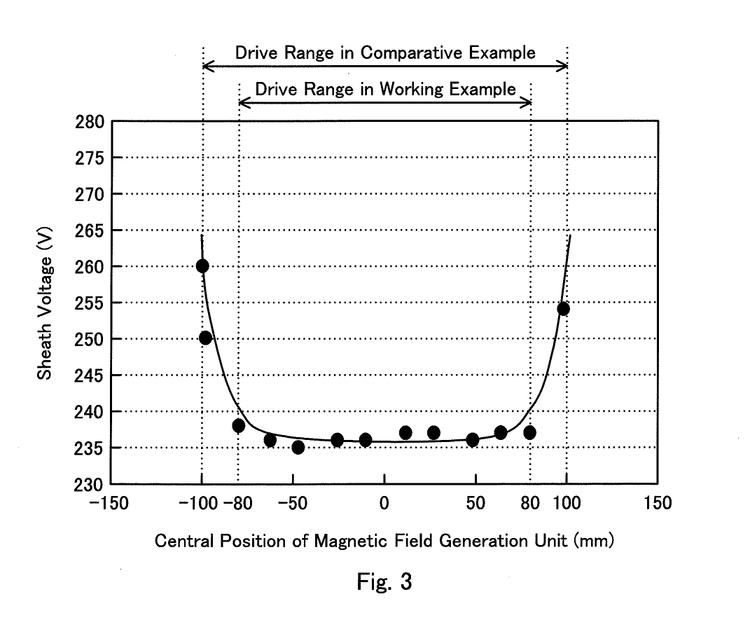

Firstly, a description of the magnitude of the sheath voltage in the comparative example and the working example shall be provided, with reference to FIG. 3. FIG. 3 is a graph illustrating the relationship between the sheath voltage and the central position of the magnetic field generation unit in a comparative example and in a working example. The horizontal axis of the graph is the center position of the magnetic field generation unit (in millimeters), and the vertical axis is the absolute value of the sheath voltage (V).

As illustrated in FIG. 3, when the magnetic field generation unit 4 is driven as in the comparative example, the absolute value of the sheath voltage when the magnetic field generation unit 4 is located at the two ends of the drive range (100 mm and −100 mm in FIG. 3) is remarkably greater than the absolute value of the sheath voltage at other positions. This is because when the magnetic field generation unit 4 is located at an end of the drive range, the plasma generated at the end part of the target Ta is caught at the grounded shield part 6 and spreads out (the plasma density in the vicinity of the target Ta decreases).

Also, when the absolute value of the sheath voltage is increased as in the comparative example, the target particles that collide with the substrate Sb or a film on the substrate Sb have a higher energy. That is, a highly damaged film will be formed on the substrate Sb.

By contrast, when the magnetic field generation unit 4 is driven as in the working example, the absolute value of the sheath voltage when the magnetic field generation unit 4 is located at the two ends of the drive range (80 mm and −80 mm in FIG. 3) can be reduced to being equivalent to the absolute value of the sheath voltage at other positions. This is because in narrowing the drive range of the magnetic field generation unit 4 as described above, the generated plasma is less likely to be caught at the grounded shield part 6 (the plasma density in the vicinity of the target Ta can be inhibited from decreasing), even when the magnetic field generation unit 4 is located at an end of the drive range.

Also, when the absolute value of the sheath voltage is decreased as in the working example, the energy of the target particles that collide with the substrate Sb or a film on the substrate Sb can be reduced. That is, a less damaged film can be formed on the substrate Sb.

As illustrated in FIG. 3, making the value of B in the aforesaid working example at least 10 mm or more makes it possible to effectively decrease the absolute value of the sheath voltage. When the value of B is 20 mm or more, the absolute value of the sheath voltage can be more effectively decreased, which is preferable.

However, as illustrated in FIG. 3, when the value of B in the aforesaid working example is increased by a certain degree or more, the absolute value of the sheath voltage can no longer be decreased. Further, when the value of B is increased too much, since the space where plasma is generated is limited, the problem that the target Ta is locally consumed arises. In view whereof, when the value of B is 30 mm or less, the absolute value of the sheath voltage can be decreased and the target Ta can be consumed uniformly, which is preferable.

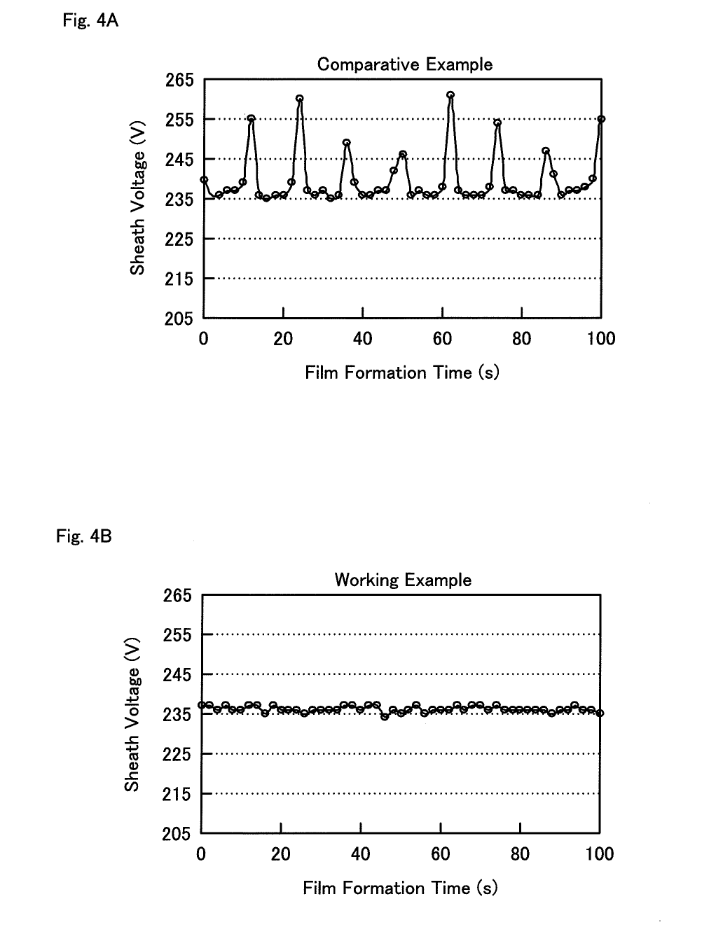

Next, a description of the temporal changes in the sheath voltage in the comparative example and the working example shall be provided, with reference to FIG. 4. FIG. 4 is a graph illustrating the relationship between the sheath voltage and the film formation time in a comparative example and in a working example. FIG. 4A is a graph illustrating the comparative example, and FIG. 4B is a graph illustrating the working example. The horizontal axes in the graphs illustrated in FIGS. 4A and 4B are film formation time (in seconds), and the vertical axes are the absolute value of the sheath voltage (V). In the graphs in FIGS. 4A and 4B, an arbitrary timing during film formation has been taken as second 0.

As illustrated in FIG. 4A, in the comparative example, the absolute value of the sheath voltage increases at each instance of a predetermined time interval. This is because the magnetic field generation unit 4 is located at an end of the drive range at each instance of the predetermined time interval. As described above, when the magnetic field generation unit 4 is located at an end of the drive range, the plasma generated at the end part of the target Ta gets caught at the grounded shield part 6, and the absolute value of the sheath voltage increases. During the film formation time illustrated in FIG. 4A, the variance of the absolute value of the sheath voltage is 26 V, and the mean value of the absolute value of the sheath voltage is 240 V.

When, as in the comparative example, the temporal changes in sheath voltage are large, the energy of the target particles that collide with the substrate Sb or the film on the substrate Sb varies greatly. That is, the film formed on the substrate Sb becomes heterogeneous.

By contrast, as illustrated in FIG. 4B, in the working example, the change in sheath voltage during the film formation time is smaller. This is because the generated plasma is less prone to get caught at the grounded shield part 6, even when the magnetic field generation unit 4 is located at an end of the drive range at each instance of the predetermined time interval, and the absolutely value of the sheath voltage is less prone to increase. During the film formation time illustrated in FIG. 4B, the variance of the absolute value of the sheath voltage is 5 V, and the mean value of the absolute value of the sheath voltage is 236 V.

When, as in the working example, the temporal changes in sheath voltage are small, the energy of the target particles that collide with the substrate Sb or the film on the substrate Sb can be rendered uniform. In other words, it becomes possible to form a homogeneous film on the substrate Sb.

As described above, in the film-forming device 1 according to the embodiment of the present invention, the absolute value of and change in the sheath voltage can be reduced merely by limiting the drive range of the magnetic field generation unit 4. It therefore becomes possible to form a film that has less damage and is homogeneous.

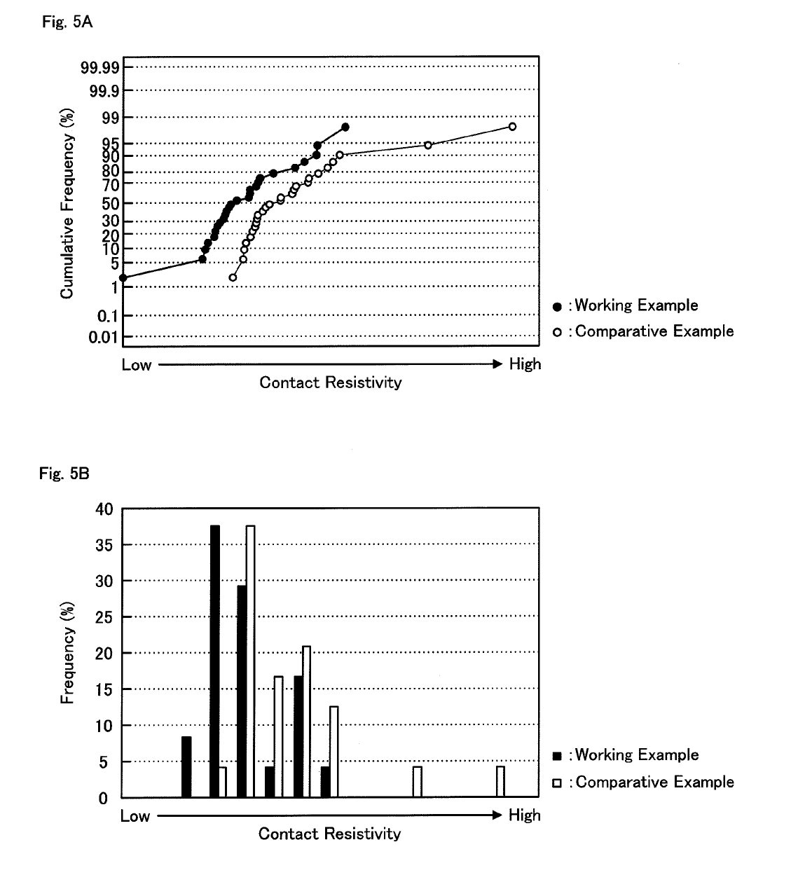

Next, the characteristics of elements provided with films formed by respective film-forming devices in which the comparative example and the working example have been adopted shall be described, with reference to FIG. 5. Specifically, the description is of the contact resistivity of an element in which a film-forming device in which the comparative example has been adopted is used to form a transparent electrode made of ITO on p-type GaN (hereinafter, the “comparative example element”), and of an element in which a film-forming device in which the working example has been adopted is used to form a transparent electrode made of ITO on p-type GaN (hereinafter, the “working example element”).

FIG. 5 is a graph illustrating the characteristics of elements provided with films formed by respective film-forming devices in which the comparative example and the working example have been adopted. The horizontal axis of the graph illustrated in FIG. 5A is contact resistivity, and the vertical axis is cumulative frequency (%). The horizontal axis of the graph illustrated in FIG. 5B is contact resistivity, and the vertical axis is frequency (%). In the graphs in FIGS. 5A and 5B, the magnitude of the contact resistivity in the comparative example element and the working example element has been normalized for the purposes of relative expression.

As described above, the film formed in the working example element is less damaged and more homogeneous than the film formed in the comparative example element. Further, because the energy of the target particles during the formation of the film (electrode) in the working example element is lower than that in the comparative example element, the damage imparted to the substrate Sb can be reduced. Therefore, as illustrated in FIGS. 5A and 5B, the distribution of contact resistivity of the working example element is overall less than the distribution of the contact resistivity of the comparative example element.

As described above, when the film-forming device 1 according to the embodiment of the present invention is used to form a transparent electrode made of ITO provided to an LED or other light-emitting devices, the characteristics of the light-emitting device can be improved. As a specific example, the threshold voltage of the light-emitting device can be reduced.

From the standpoint of forming a high-quality film, the film-forming device 1 according to the embodiment of the present invention is preferably set as follows.

For example, preferably, the distance between the substrate Sb and the target Ta is 50 mm or more to 150 mm or less, and the distance between the target Ta and the magnetic field generation unit 4 is 15 mm or more and 30 mm or less. Preferably, the drive unit 5 drives the magnetic field generation unit 4 at a speed, for example, of 10 mm/s or more and 20 mm/s or less. Preferably, the magnetic flux density in the region facing the magnetic field generation unit 4 in the front surface of the target Ta is, for example, 0.03 T or more and 0.12 T or less. Preferably, the interior of the chamber 7 when a film is being formed is, for example, an argon atmosphere of 0.4 Pa or more and 1 Pa or less. Preferably, the temperature of the substrate Sb when a film is being formed is, for example, 50° C. or less (room temperature or more; the substrate is not heated). Preferably, the direct current power supplied to the target Ta (the backing plate 3) when a film is being formed is, for example, 200 W or more and 1,200 W or less.

As an example, an increase the magnetic flux density of the magnetic field generation unit 4 has an advantage that the absolute value of the sheath voltage can be reduced, whereas it has a disadvantage that cost is increased because the device becomes larger or more complex, or the design of the device needs to be extensively modified with the increased size or complexity of the magnet. Therefore, the magnetic flux density of the magnetic field generation unit 4 is preferably made to fall within the aforesaid range, thus eliminating the flaws, and the drive range of the magnetic field generation unit 4 is limited, thus reducing the absolute value of and changes in the sheath voltage.

Also, the optimum value in the set ranges can vary depending on the structure of the film-forming device, the type of film being generated, and the like. For example, in the film-forming device 1 according to the embodiment of the present invention, the aforesaid film formation conditions are optimum values.

In the film-forming device 1 according to the embodiment of the present invention, the distance in the drive direction between the magnetic field generation unit 4 and the projection when the shield part 6 is projected perpendicularly to the horizontal plane has been defined, but the distance in the direction perpendicular to the drive direction (the length direction of the magnetic field generation unit 4) may also similarly be defined. That is, the distance in the direction perpendicular to the drive direction between the magnetic field generation unit 4 and the projection when the shield part 6 is projected perpendicularly to the horizontal plane may be 10 mm or more (preferably, 20 mm or more, and preferably 30 mm or less). However, in such a case, it may in some cases become necessary to alter the design of the film-forming device, such as by shortening the length of the length direction of the magnetic field generation unit 4.

When the magnetic field generation unit 4 is rod-shaped, as in the film-forming device 1 according to the embodiment of the present invention described above, plasma can be generated along the length direction of the magnetic field generation unit 4, and therefore the distance between either side surface in the length direction of the magnetic field generation unit 4 and the shield part 6 has a major influence on the sheath voltage. Accordingly, it is possible to adequately reduce the sheath voltage also merely by defining the distance in the drive direction between the magnetic field generation unit 4 and the projection when the shield part 6 is projected perpendicularly to the horizontal plane. Further, when the configuration is such, there is no need to change the magnetic field generation unit 4 or the like; merely the method for driving the magnetic field generation unit 4 with the drive unit 5 need be changed. Therefore, the present invention can be readily applied to a conventional film-forming device.

The present invention can also be applied to a film-forming device other than the film-forming device 1, in which the magnetic field generation unit 4 is driven reciprocatingly in a linear manner. As a specific example, the present invention can also be applied to a film-forming device in which the magnetic field generation unit is driven so as to be rotated. In any case where the present invention is applied to any film-forming device, the distance between the magnetic field generation unit and the projection when the shield part is projected perpendicularly to the horizontal plane when the magnetic field generation unit is located at an end of the drive range (or, in some cases, at all times) may be 10 mm or more (preferably 20 mm or more, preferably 30 mm or less).

However, when the present invention is applied to a film-forming device in which there is great overlap between the edge of the region where plasma is generated and the edge of the shield part, as in the film-forming device 1 according to the embodiment of the present invention described above, the sheath voltage can be effectively decreased, which is particularly preferable.

The present invention can be used in a magnetron sputtering device or other film-forming devices, and in a light-emitting device provided with an electrode formed by the film-forming device.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A film-forming device for forming, on a substrate placed toward a front surface of a target, a film containing a material constituting the target, by sputtering the target with plasma, the film-forming device comprising:
a chamber in an interior of which the film is formed;
a shield part placed within the chamber so as to surround sides of the target;
a rod-shaped magnetic field generation unit for generating a magnetic field, the magnetic field generation unit being placed inside the shield part and toward a back surface of the target; and
a drive unit for reciprocatingly driving the magnetic field generation unit in a linear manner along a drive direction, which is a direction perpendicular to a length direction of the magnetic field generation unit, in a horizontal plane, which is a plane perpendicular to a front/back direction of the target; wherein
when the magnetic field generation unit is located at an end of a range within which the magnetic field generation unit is driven by the drive unit, a distance in the drive direction between the magnetic field generation unit and a projection when the shield part is projected perpendicularly to the horizontal plane is 10 mm or more.

2. The film-forming device according to claim 1, wherein
when the magnetic field generation unit is located at the end of the range within which the magnetic field generation unit is driven by the drive unit, the distance in the drive direction between the magnetic field generation unit and the projection when the shield part is projected perpendicularly to the horizontal plane is 20 mm or more.

3. The film-forming device according to claim 1, wherein
a polarity of the magnetic field generation unit on a target side and on an outer peripheral side in the horizontal plane is different from the polarity of the magnetic field generation unit on the target side and on a center in the horizontal plane.

4. The film-forming device according to claim 1, wherein
when the magnetic field generation unit is located at the end of the range within which the magnetic field generation unit is driven by the drive unit, the distance in the drive direction between the magnetic field generation unit and the projection when the shield part is projected perpendicularly to the horizontal plane is 30 mm or less.

5. The film-forming device according to claim 1, wherein
the drive unit drives the magnetic field generation unit at a speed of 10 mm/s or more and 20 mm/s or less.

6. The film-forming device according to claim 1, wherein
a distance between the substrate and the target is 50 mm or more and 150 mm or less, and
a distance between the target and the magnetic field generation unit is 15 mm or more and 30 mm or less.

7. The film-forming device according to claim 1, wherein
a magnetic flux density of a region facing the magnetic field generation unit in the front surface of the target is 0.03 T or more and 0.12 T or less.

8. The film-forming device according to claim 1, wherein
the interior of the chamber when the film is being formed is an argon atmosphere of 0.4 Pa or more and 1 Pa or less.

9. The film-forming device according to claim 1, wherein
temperature of the substrate when the film is being formed is 50° C. or less.

10. The film-forming device according to claim 1, wherein
direct current power supplied to the target when the film is being formed is 200 W or more and 1,200 W or less.

11. A film-forming device for forming, on a substrate placed toward a front surface of a target, a film containing a material constituting the target, by sputtering the target with plasma, the film-forming device comprising:
a chamber in an interior of which the film is formed;
a shield part placed within the chamber so as to surround sides of the target;
a magnetic field generation unit for generating a magnetic field, the magnetic field generation unit being placed inside the shield part and toward a back surface of the target; and
a drive unit for driving the magnetic field generation unit in a horizontal plane, which is a plane perpendicular to a front/back direction of the target; wherein
when the magnetic field generation unit is located at an end of a range within which the magnetic field generation unit is driven by the drive unit, a distance between the magnetic field generation unit and a projection when the shield part is projected perpendicularly to the horizontal plane is 10 mm or more.

12. A light-emitting device, comprising:
an electrode made of indium tin oxide formed with the film-forming device according to claim 1.
